(19) United States
(12) Patent Application Publication
(10) Pub. No.: US 2025/0380456 A1
(43) Pub. Date: Dec. 11, 2025

(54) INCREASED BACKSIDE SOURCE/DRAIN CONTACT AREA AND SOURCE/DRAIN VOLUME

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Oleg Gluschenkov, Tannersville, NY (US)

(21) Appl. No.: 18/734,813

(22) Filed: Jun. 5, 2024

(51) Int. Cl. H01L 29/423; H01L 21/762; H01L 21/8234; H01L 27/088; H01L 29/06; H01L 29/417; H01L 29/66; H01L 29/775; H01L 29/786

(52) U.S. Cl. CPC H10D 30/6735; H01L 21/76224; H10D 30/014; H10D 30/43; H10D 30/6757; H10D 62/121; H10D 64/258; H10D 84/013; H10D 84/0149; H10D 84/0151; H10D 84/038; H10D 84/83

(57) ABSTRACT

A semiconductor device is provided in which the backside source/drain contact area and the source/drain volume are increased by reducing a height of the shallow trench isolation structure.

### BACKGROUND

The present application relates to semiconductor technology, and more particularly to a semiconductor device in which the backside source/drain contact area and the source/drain volume are increased by reducing a height of the shallow trench isolation structure.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance). Also, placing the power lines on the backside can reduce interference with signal paths and minimize heat buildup near the active device regions.

### SUMMARY

A semiconductor device is provided in which the backside source/drain contact area and the source/drain volume are increased by reducing a height of the shallow trench isolation structure. Such a device avoids epi volume loss especially at the bottommost device channel.

In one aspect of the present application, the semiconductor device includes a pair of transistors located adjacent to each other, each transistor of the pair of transistors includes a gate structure and source/drain regions. The semiconductor device further includes a gate cut dielectric pillar separating the gate structures of the pair of transistors, a dielectric pillar structure separating the source/drain regions of the pair of transistors, and a backside back-end-of-the-line (BEOL) structure electrically connected to a first source/drain region of a first transistor of the pair of transistors by a backside source/drain contact structure. In the present application, the first source/drain region wraps around an upper portion of the backside source/drain contact structure, and the backside source/drain contact structure is located entirely beneath the gate structure of the pair of transistors.

In another aspect of the present application, the semiconductor device includes a pair of transistors located adjacent to each other, each transistor of the pair of transistors includes a gate structure and source/drain regions. The semiconductor device further includes a gate cut dielectric pillar separating the gate structures of the pair of transistors, a dielectric pillar structure separating the source/drain regions of the pair of transistors, and a backside back-end-of-the-line (BEOL) structure electrically connected to a first source/drain region of a first transistor of the pair of transistors by a backside source/drain contact structure. In the present application, the first source/drain region wraps around an upper portion of the backside source/drain contact structure, and the source/drain regions have a bottommost surface that is vertically offset and located below a bottommost surface of each gate structure.

### BRIEF DESCRIPTION OF THE DRAWINGS

FIG. 1 is a top down view of a device layout that can be employed in accordance with an embodiment of the present application.

FIGS. 2A-2B are cross sectional views of an exemplary structure through cuts A-A and B-B respectively of FIG. 1 that can be used in accordance with an embodiment of the present application, the exemplary structure including a material stack of alternating sacrificial semiconductor material layers and semiconductor channel material layers, the material stack being located on a placeholder layer that is positioned on a substrate.

FIGS. 3A-3B are cross sectional views of the exemplary structure of FIGS. 2A-2B, respectively, after forming a sacrificial gate structure, a gate spacer and a bottom dielectric isolation layer, etching the material stack utilizing the sacrificial gate structure and the gate spacer as a combined etch mask to provide a nanosheet stack of alternating sacrificial semiconductor material nanosheets and semiconductor channel material nanosheets, recessing each sacrificial semiconductor material nanosheet of the nanosheet stack, forming inner spacers, and forming backside source/drain contact placeholder structures in an upper portion of the substrate.

FIG. 3C is a cross sectional view of the exemplary structure of FIGS. 3A-3B through cut C-C shown in FIG. 1.

FIGS. 4A-4C are cross sectional views of the exemplary structure of FIGS. 3A-3C, respectively, after forming a semiconductor buffer layer and source/drain regions.

FIGS. 5A-5C are cross sectional views of the exemplary structure of FIGS. 4A-4C, respectively, after forming a first frontside interlayer dielectric (ILD) layer, and forming a dielectric pillar structure between source/drain regions of different device areas.

FIGS. 6A-6C are cross sectional views of the exemplary structure of FIGS. 5A-5C, respectively, after revealing the nanosheet stack, removing each sacrificial semiconductor material nanosheet from the nanosheet stack, and then forming a gate structure, a middle-of-the-line (MOL) level, a frontside back-end-of-the-line (BEOL) structure, and a carrier wafer.

FIGS. 7A-7C are cross sectional views of the exemplary structure of FIGS. 6A-6C, respectively, after wafer flipping and removing a semiconductor base layer of the substrate to physically expose an etch stop layer of the substrate.

FIGS. 8A-8C are cross sectional views of the exemplary structure of FIGS. 7A-7C, respectively, after removing the etch stop layer and a semiconductor device layer of the substrate, and forming a backside ILD layer.

FIGS. 9A-9C are cross sectional views of the exemplary structure of FIGS. 8A-8C, respectively, after forming backside source/drain contact openings that reveal some of the backside source/drain contact placeholder structures.

FIGS. 10A-10C are cross sectional views of the exemplary structure of FIGS. 9A-9C, respectively, after forming a backside source/drain contact structure in each of the backside source/drain contact openings.

FIGS. 11A-11C are cross sectional views of the exemplary structure of FIGS. 10A-10C, respectively, after forming a backside BEOL structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside BEOL structure. The backside BEOL structure can be a backside power distribution network that is capable of delivering power to the transistor through the backside of the semiconductor device.

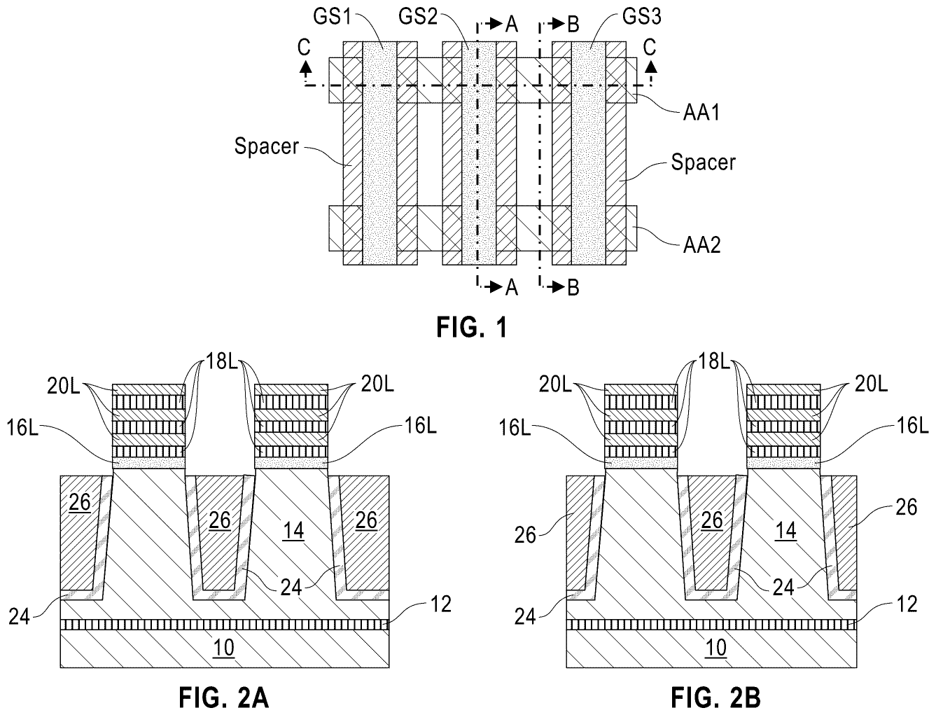

Referring first to FIG. 1, there is illustrated a device layout that can be employed in accordance with an embodiment of the present application. The illustrated device layout includes two active device areas, AA1 and AA2. AA1 is a first active device area in which first transistors can be formed, and AA2 is a second active device area in which second transistors can be formed. In FIG. 1, three gate structures, GS1, GS2 and GS3 are shown by way of one example. The present application is not limited to using three gate structures. The gate structures run parallel to each other and perpendicular to each of the active device areas. A spacer is also shown along the sidewall of each gate structure. FIG. 1 also includes three different cuts, namely cut A-A, cut B-B, and cut C-C that will be used throughout the remaining drawings of the present application. Cut A-A is a cut that runs in a length wise direction through a portion of the second gate structure GS2 and it passes through each of AA1 and AA2. Cut A-A shows a first transistor and a second transistor that make-up a pair of transistors in accordance with the present application. Cut B-B is a cut that runs in a length wise direction between the second gate structure, GS2, and the third gate structure, G3 and it passes through each of AA1 and AA2. Notably, cut B-B will show the source/drain areas of first and second transistors of the present application. Cut C-C is a cut that runs in a length wise direction through the middle of AA1. Notably, cut C-C shows the first active device area AA1 including the first transistors.

Referring now to FIGS. 2A-2B, there are illustrated an exemplary structure through cuts A-A and B-B respectively of FIG. 1 that can be used in accordance with an embodiment of the present application. The illustrated exemplary structure of FIGS. 2A-2B includes a material stack of alternating sacrificial semiconductor material layers 18L and semiconductor channel material layers 20L, the material stack being located on a placeholder layer 16L that is positioned on a substrate. It is noted that the material stack and the placeholder layer 16L are both located on top of an active device area of the substrate. A shallow trench isolation structure can be located between different active device regions.

The substrate includes at least a semiconductor device layer 14. In addition to the semiconductor device layer 14, the substrate can also include a semiconductor base layer 10 and/or an etch stop layer 12. Embodiments are contemplated in which the semiconductor base layer 10 and/or the etch stop layer 12 are omitted and the substrate includes only the semiconductor device layer 14. The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

The placeholder layer 16L is composed of a fourth semiconductor material. The fourth semiconductor material layer that provides the placeholder layer 16L is compositionally different from the second semiconductor material that provides the semiconductor device layer 14. The fourth semiconductor material that provides the placeholder layer 16L is also designed to be compositionally different from the semiconductor materials that provide the sacrificial semiconductor material layers 18L and the semiconductor channel material layers 20L of the material stack.

Each sacrificial semiconductor material layer 18L is composed of a fifth semiconductor, while each semiconductor channel material layer 20L is composed of a sixth semiconductor material. In the present application, the sixth semiconductor material is compositionally different from both the fourth semiconductor material and the fifth semiconductor material, and the fifth semiconductor material is different from the fourth semiconductor material. In some embodiments, the sixth semiconductor material that provides each semiconductor channel material layer 20L provides high channel mobility for NFET devices. In other embodiments, the sixth semiconductor material that provides each semiconductor channel material layer 20L provides high channel mobility for PFET devices. In one example, each semiconductor channel material layer 20L is composed of silicon, each sacrificial semiconductor material layer 18L is composed of a SiGe alloy having a first Ge content, and the placeholder layer 16L is composed of a SiGe alloy having a second Ge content that differs from the first Ge content. The material stack of alternating sacrificial semiconductor material layers 18L and semiconductor channel material layers 20L can be formed utilizing one or more deposition processes including, for example, CVD, PECVD and epitaxial growth as defined above. In the present application, the material stack typically includes “n” number of sacrificial semiconductor material layers 18L and “n” number of semiconductor channel material layers 20L in which n is at least 2.

The exemplary structure illustrated in FIGS. 2A-2B can be formed utilizing techniques well known in the art. For example, the exemplary structure can be formed by forming the sacrificial semiconductor material layer 16L on the semiconductor device layer 14 of the substrate. The placeholder layer 16L can be formed by a deposition process such as, for example, chemical vapor deposition (CVD), plasma enhanced chemical vapor deposition (PECVD) or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking.

After forming the placeholder layer 16L, one or more deposition processes (including CVD, PECVD and/or epitaxial growth) are used in forming alternating sacrificial semiconductor material layers 18L and semiconductor channel material layers 20L. A patterned hard mask (not shown) is then formed on top of the as-deposited material stack. The patterned hard mask can be composed of a hard mask material such as, for example, silicon dioxide, silicon nitride and/or silicon oxynitride. The patterned hard mask can be formed by deposition, followed by lithographic patterning. Lithographic patterning includes forming a photoresist material on a layer/multilayered stack that needs to be patterned, exposing the as deposited photoresist material to a desired pattern of irradiation, developing the photoresist material and transferring the patterned from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In the present application, the patterned hard mask includes openings in which a portion of the underlying as deposited material stack is physically exposed; the patterned hard mask is used in defining active device areas. With the patterned hard mask in place, an etch (dry etching and/or wet etching) can be used to remove portions of the as-deposited material stack and as-deposited placeholder layer 16L that are not protected by the patterned hard mask. The etch defines the active device areas in which the placeholder layer 16L and the material stack are present.

The shallow trench isolation structure is formed after forming the active device areas by etching a trench into an upper portion of the semiconductor device layer 14, and then forming a trench dielectric liner 24 and a trench dielectric material 26 in the trench. In some embodiments, the trench dielectric liner 24 is not present. The trench dielectric liner 24 is composed of any trench dielectric liner material, while the trench dielectric material 26 is composed of any trench dielectric material. In one example, the trench dielectric liner 24 is composed of silicon nitride, and the trench dielectric material 26 is composed of silicon dioxide. The forming of the trench dielectric liner 24 and the trench dielectric material 26 in the trench includes first depositing a layer of the trench dielectric liner material, second depositing a trench dielectric material on the layer of trench dielectric liner material, and then performing an etch back process. The shallow trench isolation structure can have a topmost surface that is substantially coplanar with a topmost surface of the semiconductor device layer 14. The patterned hard mask can be removed between the formation of the active device areas and the shallow trench isolation structure, or after formation of the shallow trench isolation structure. The patterned hard mask can be removed utilizing a material removal process such as, for example, etching or planarization.

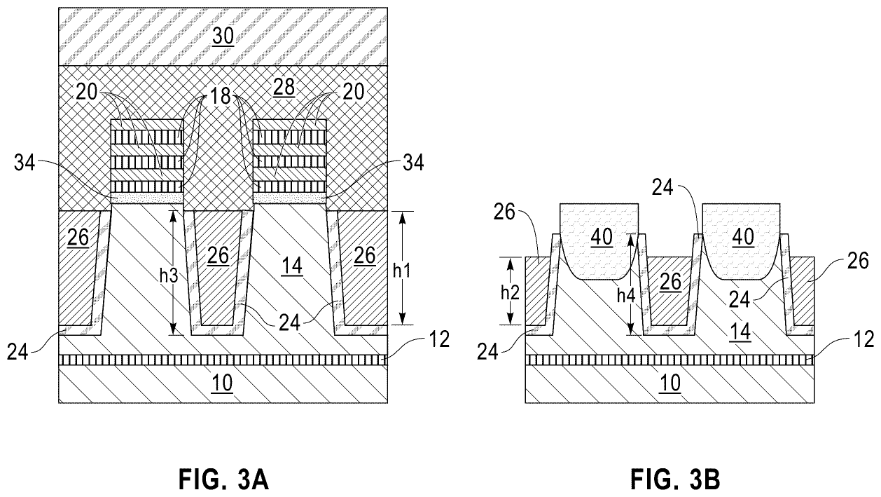

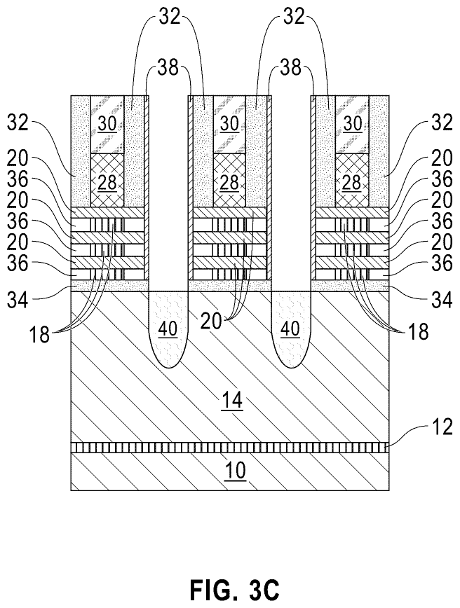

Referring now to FIGS. 3A-3B, there are illustrated the exemplary structure of FIGS. 2A-2B, respectively, after forming a sacrificial gate structure 28, a gate spacer 32 and a bottom dielectric isolation layer 34, etching the material stack utilizing the sacrificial gate structure 28 and the gate spacer 32 as a combined etch mask to provide a nanosheet stack of alternating sacrificial semiconductor material nanosheets 18 and semiconductor channel material nanosheets 20, recessing each sacrificial semiconductor material nanosheet 18 of the nanosheet stack, forming inner spacers 36, and forming backside source/drain contact placeholder structures 40 in an upper portion of the substrate. FIG. 3C illustrates the exemplary structure of FIGS. 3A-3B through cut C-C shown in FIG. 1.

In some embodiments, a sacrificial gate cap 30 can be present on top of the sacrificial gate structure 28. In other embodiments, the sacrificial gate cap 30 can be omitted. The sacrificial gate structure 28, which straddles each material stack, is composed of at least a sacrificial gate material. The sacrificial gate structure 28 can also include an optional sacrificial gate dielectric material (not shown in the drawings) located beneath the sacrificial gate material. When present, the sacrificial gate dielectric material is composed of a dielectric material such as, for example, silicon dioxide. The sacrificial gate material can include, but is not limited to, polysilicon, amorphous silicon, amorphous silicon germanium, tungsten (W), titanium (Ti), tantalum (Ta), nickel (Ni), ruthenium (Ru), palladium (Pd) platinum (Pt) or alloys of such metals. When present, the sacrificial gate cap 30 is composed of a hard mask material such as, for example, silicon dioxide, silicon nitride and/or silicon oxynitride. The sacrificial gate structure 28 and the sacrificial gate cap 30 can be formed by first depositing a blanket layer of at least the sacrificial gate material, followed by second depositing a blanket layer of hard mask material; the second depositing step is optional and need not be performed in all embodiments. The blanket layers are then patterned by lithography and etching to provide the sacrificial gate structure 28 and sacrificial gate cap 30.

After forming the sacrificial gate structure 28 and if present, the sacrificial gate cap 30, the gate spacer 32 and the bottom dielectric isolation layer 34 are formed simultaneously. Notably, the gate spacer 32 and the bottom dielectric isolation layer 34 are formed by first performing an etch that is selective in removing the patterned placeholder layer 16L from beneath each patterned material stack; a gap is formed beneath each patterned material stack. The patterned material stack is anchored in place by at least the sacrificial gate structure 28. A dielectric spacer material is then deposited filling in the gap and continues along a sidewall of the sacrificial gate structure 28 and if, present, a sidewall of the sacrificial gate cap 30. A spacer etch is then performed forming the gate spacer 32 along the sidewall of the sacrificial gate structure 28 and if, present, the sidewall of the sacrificial gate cap 30, and the bottom dielectric isolation layer 34 is formed in the gap that is located beneath each patterned material stack. The dielectric spacer material can include, silicon dioxide, SIN, SiBCN, SiOCN or SiOC.

The etching of the material stack includes one or more etching processes that stop on the bottom dielectric isolation layer 34. In one example, the etching of the material stack includes RIE. Note that the material sack is completely removed from the source/drain area that is illustrated in FIG. 3B. As mentioned above, the nanosheet stack includes alternating sacrificial semiconductor material nanosheets 18 and semiconductor channel material nanosheets 20. The sacrificial semiconductor material nanosheets 18 are non-etched portions of the sacrificial semiconductor layers 18L in the material stack, while the semiconductor channel material nanosheets 20 are non-etched portions of the semiconductor channel material layers 20L in the material stack.

After forming the nanosheet stack, each sacrificial semiconductor material nanosheet 18 of the nanosheet stack is recessed utilizing a lateral etching process. A gap is formed next to each recessed sacrificial semiconductor material nanosheet 18. Inner spacer 36 is formed in each gap by depositing a spacer dielectric material as described above, and then performing an inner spacer formation etch.

The formation of the backside source/drain contact placeholder structures 40 includes forming a sacrificial liner 38 along a sidewall of each of following: the gate spacer 32, each semiconductor channel material nanosheet 20 and each inner spacer 36. The sacrificial liner 38 can be composed of a dielectric material such as, for example, aluminum oxide or titanium oxide. The sacrificial liner 38 can be formed by deposition, followed by a directional etch the removes sacrificial liner 38 from all horizontal surfaces of the exemplary structure. With the sacrificial liner 38 in place, a punch through etch is performed to remove physically exposed portions of the bottom dielectric isolation layer 34. The punch through etch removes the bottom dielectric isolation layer 34 from the area in which source/drain regions will be subsequently formed. Trenches are then formed in the semiconductor device layer 14 by etching. Backside source/drain contact placeholder structures 40 are then formed in the trenches by deposition (e.g., CVD, PECVD or epitaxial growth) of a seventh semiconductor material, and then performing an etch back process. Each backside source/drain contact placeholder structure 40 is composed of a remaining portion of the as-deposited seventh semiconductor material. The seventh semiconductor material that provides each backside source/drain contact placeholder structure 40 is compositionally different from at least the second semiconductor material that provides the semiconductor device layer 14. Each backside source/drain contact placeholder structure 40 has a topmost surface that is substantially coplanar with a topmost surface of the semiconductor device layer 14. The sacrificial liner 38 is removed any time after defining the trenches that house the backside source/drain contact placeholder structures 40.

It is noted that the shallow trench isolation structures that are located beneath the sacrificial gate structure 28 have a topmost surface that is substantially coplanar with a topmost surface of the semiconductor device layer 14 (See, for example, FIG. 3A). The shallow trench isolation structure not protected by the sacrificial gate structure 28 is exposed to many etching processes during the formation of the exemplary structure shown in FIGS. 3A-3C. These various etching processes pull down the trench dielectric material 26 and the trench dielectric liner 24 as shown in FIG. 3B. Notably, the trench dielectric material 26 of the shallow trench isolation structures located beneath the sacrificial gate sacrificial gate structure 28 have a first height h1 and the trench dielectric material 26 of the shallow trench isolation structures not located beneath the sacrificial gate sacrificial gate structure 28 have a second height h2 in which h2 is less than h1. Similarly, and if present, the trench dielectric liner 24 of the shallow trench isolation structures located beneath the sacrificial gate sacrificial gate structure 28 have a third height h3 and the trench dielectric liner 24 of the shallow trench isolation structures not located beneath the sacrificial gate sacrificial gate structure 28 have a fourth height h4 in which h4 is less than h3. Because of this pull down, sidewalls of the backside source/drain contact placeholder structures 40 that are located in the source/drain regions as shown in FIG. 3B are physically exposed allowing for an increased surface area in which source/drain regions 44 can subsequently be formed on.

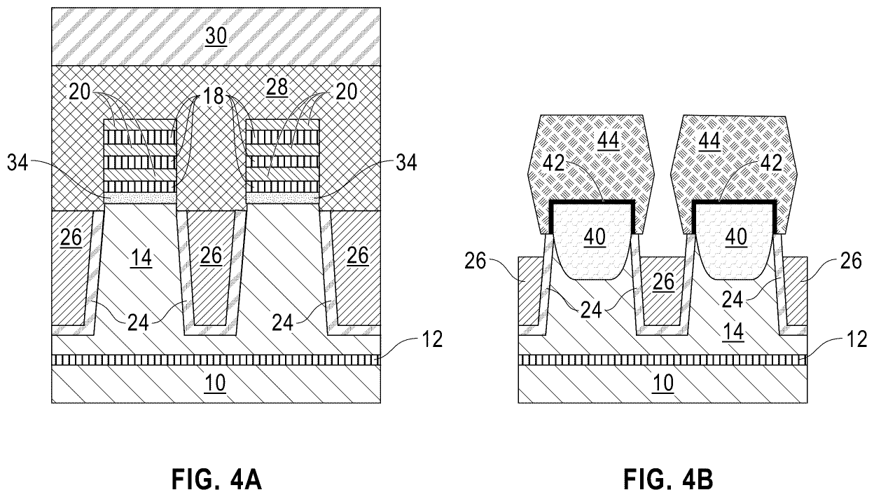

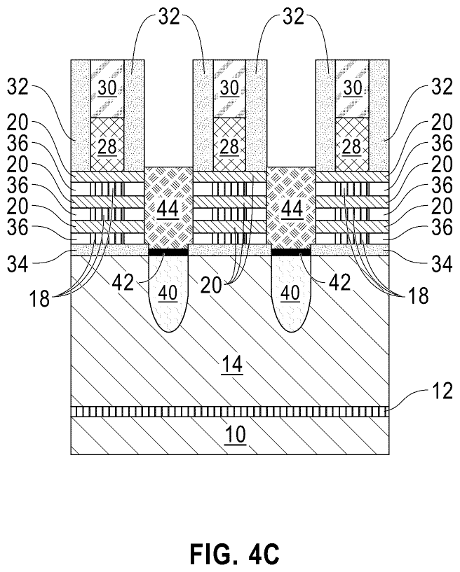

Referring now to FIGS. 4A-4C, there are illustrated the exemplary structure of FIGS. 3A-3C, respectively, after forming a semiconductor buffer layer 42 and source/drain regions 44. Semiconductor buffer layer 42 can be omitted in some embodiments of the present application. When present, the semiconductor buffer layer 42 is composed of an eighth semiconductor material. The eighth semiconductor material is compositionally different from the seventh semiconductor material that provides the backside source/drain contact placeholder structures 40. The semiconductor buffer layer 42 is typically used to facilitate the formation of the source/drain regions 44. The semiconductor buffer layer 42 is generally located above the topmost surface of the substrate (e.g., the topmost surface of the semiconductor device layer 14), but not above a bottom surface of the bottommost semiconductor channel material nanosheet of the nanosheet stack. The semiconductor buffer layer 42 can be formed by a deposition process such as, for example, CVD, PECVD or epitaxial growth. An etch back process can follow the deposition used in providing the semiconductor buffer layer 42. The semiconductor buffer layer 42 is located on a topmost surface and along physically exposed sidewalls of the backside source/drain contact placeholder structures 40.

Each source/drain region 44 is composed of a ninth semiconductor material and a dopant. The dopant can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region 44 can have a dopant concentration of from 4×10²⁰ atoms/cm³ to 3×10²¹ atoms/cm³. The source/drain regions 44 can be formed by a deposition process such as, for example, CVD, PECVD or epitaxial growth. An etch back process can follow the deposition used in providing the source/drain regions 44. Note that the source/drain regions 44 grow outward from a physically exposed sidewall of each semiconductor channel material nanosheet 20 that is present in the nanosheet stack. Each source/drain region 44 is located on a topmost surface and along physically exposed sidewalls of the semiconductor buffer layer 42 or the backside source/drain contact placeholder structure 40 when no semiconductor buffer layer 42 is present. Notably, each source/drain region 44 wraps around an upper portion of the backside source/drain contact placeholder structures 40, as is illustrated in FIG. 4B.

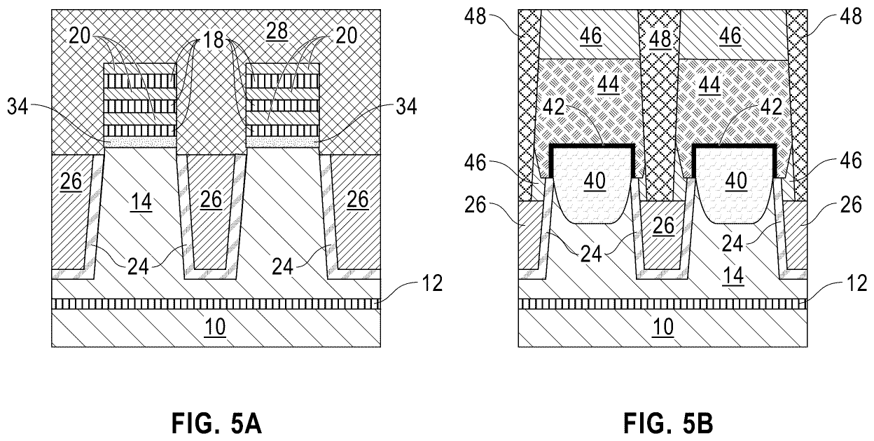

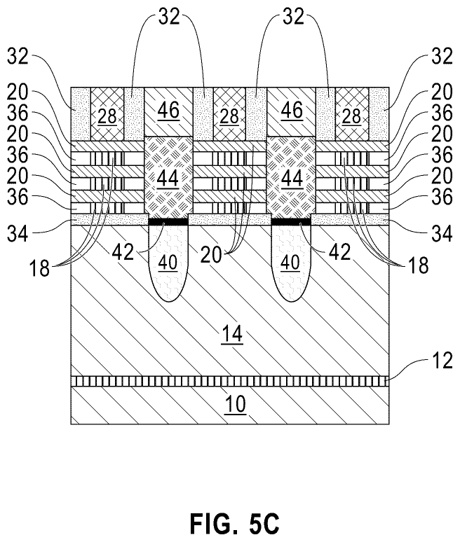

Referring now to FIGS. 5A-5C, there are illustrated the exemplary structure of FIGS. 4A-4C, respectively, after forming a first frontside ILD layer 46, and forming a dielectric pillar structure 48 between source/drain regions 44 of different device areas. The first frontside ILD layer 46 is composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are relative to a vacuum unless otherwise noted. The first frontside ILD layer 46 can be formed by a deposition process (e.g., CVD, PECVD or spin-on coating), followed by a planarization process. Throughout the present application, a planarization process can include grinding and/or chemical mechanical planarization (CMP). It is noted that during the planarization process the sacrificial gate cap 30 and an upper portion of each gate spacer 32 can be removed. The first frontside ILD layer 46 typically has a topmost surface that is substantially coplanar with a topmost surface of the sacrificial gate structure 28.

Dielectric pillar structure 48 is then formed in the area including the source/drain regions 44 as is shown in FIG. 5B. The dielectric pillar structure 48 bisects neighboring source/drain regions 44. The dielectric pillar structure 48 is composed of at least one dielectric material such as, for example, SiC or SiOC. The dielectric material that provides the dielectric pillar structure 48 is typically compositionally different from the ILD material that provides the first frontside ILD layer 46. The dielectric pillar structure 48 can be formed by first forming (by lithography and etching) a dielectric pillar trench into the first frontside ILD layer 46. The dielectric pillar trench extends through the first frontside ILD layer 46 and lands on a surface of trench dielectric material having the second height. During the etch that forms the dielectric pillar structure 48, a sidewall portion of each neighboring source/drain region 44 can be cut as shown in FIG. 5B. After forming the dielectric pillar trench, a deposition process is used to fill the dielectric pillar trench, and a planarization process can follow the deposition process to provide the dielectric pillar structure 48 shown in FIG. 5B. The dielectric pillar structure 48 typically has a topmost surface that is coplanar with a topmost surface of the first frontside ILD layer 46. It is noted that the formation of dielectric pillar structure 48 is performed to avoid any merging of the source/drain regions 44 between neighboring transistors. Also, it is noted that a portion of the first frontside ILD layer 46 remains beneath the source/drain regions 44.

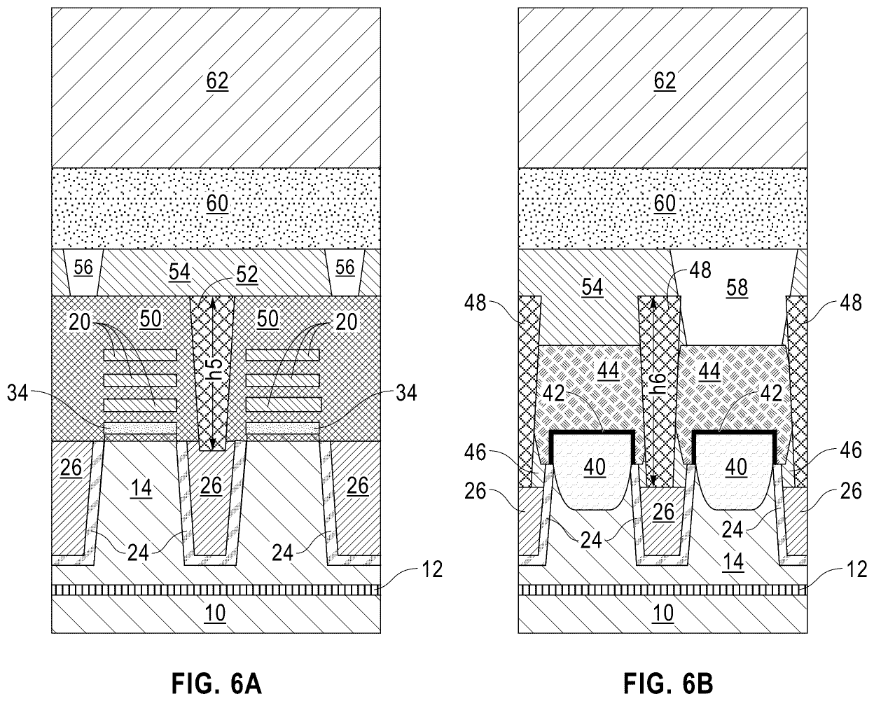

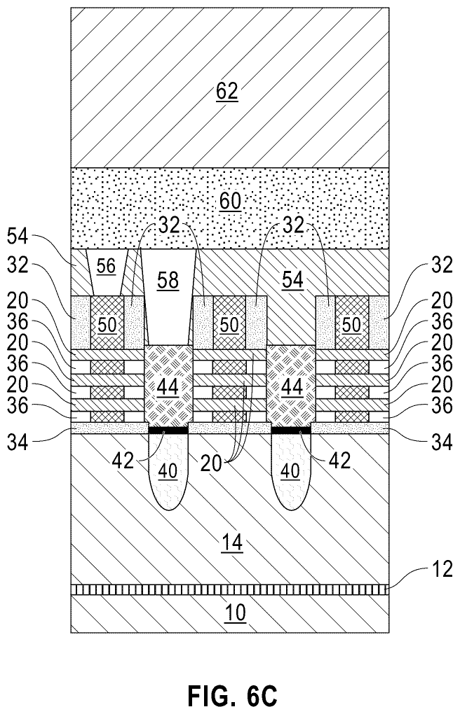

Referring now to FIGS. 6A-6C, there are illustrated the exemplary structure of FIGS. 5A-5C, respectively, after revealing the nanosheet stack, removing each sacrificial semiconductor material nanosheet 18 from the nanosheet stack, and then forming a gate structure 50, a MOL level, a frontside BEOL structure 60, and a carrier wafer 62.

The revealing the nanosheet stack includes removing the sacrificial gate structure 28. The sacrificial gate structure 28 can be removed utilizing a material removal process such as, for example, RIE, that is selective in removing the sacrificial gate structure 28. Each sacrificial semiconductor material nanosheet 18 of the revealed nanosheet stack is then removed utilizing a material removal process such as, for example, another RIE, that is selective in removing each sacrificial semiconductor material nanosheet 18. The removal of each sacrificial semiconductor material nanosheet 18 suspends a portion of each semiconductor channel material nanosheet 20 of the nanosheet stack.

The gate structure 50 includes a gate dielectric material and a gate electrode, both of which are not separately shown, but intended to be within the region defined by the gate structure 50. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure 50 can be formed by deposition, followed by planarization.

After forming the gate structure 50, the gate structure 50 is cut as shown in FIG. 6A. The cutting of the gate structure 50 includes forming a gate cut pillar 52 that passes through the gate structure 50 and lands on a surface of trench dielectric material that has the first height. The gate cut pillar 52 is composed of at least one dielectric material such as, for example, SiC or SiOC. The gate cut pillar 52 can be formed by first forming (by lithography and etching) a gate cut trench into the gate structure 50. After forming the gate cut trench, a deposition process is used to fill the gate cut trench, and a planarization process can follow the deposition process to provide the gate cut pillar 52 shown in FIG. 6A. The gate cut pillar 52 typically has a topmost surface that is substantially coplanar with a topmost surface of each gate structure 50. The gate cut pillar 52 has a height h5 that is less than a height h6 of the dielectric pillar structure 48, yet the gate cut pillar 52 and the dielectric pillar structure 48 have topmost surfaces that are substantially coplanar with each other.

The MOL level is now formed. The MOL level formation includes forming a second frontside ILD layer (not specifically labeled in FIGS. 6A-6C). Collectively, the first frontside ILD layer 46 and the second frontside ILD layer provide a multi-layered MOL structure 54. The second frontside ILD layer can be composed of compositionally same, or compositionally different, ILD material than the frontside ILD layer. When the first frontside ILD layer 46 and the second frontside ILD layer are composed of a compositionally same ILD material, no material interface is present between the two ILD layers (such an embodiment in illustrated in FIGS. 6A-6C). When the first frontside ILD layer 46 and the second frontside ILD layer are composed of compositionally different ILD materials, a material interface (not shown) is present between the two ILD layers. The second frontside ILD layer can be formed by a deposition process, followed by a planarization process. The MOL level formation continues by forming various frontside contact structures including frontside source/drain contact structures 58 and frontside gate contact structures 56. In the present application, each frontside source/drain contact structure 58 contacts one of the source/drain regions 44 of one of the transistors, while each frontside gate contact structure 56 contacts a gate electrode of the gate structure 50 of at least one of the transistors Each of the frontside contact structures is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. Each of frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. Each of the frontside contact structures can be formed by a metallization process which includes forming (by lithography and etching) frontside contact openings in at least some of the ILD layers that provide the MOL multi-layered structure 54, and then filling each frontside contact opening with at least a contact conductor material as defined above. The filling of each frontside contact opening can include a deposition process (such as, for example, CVD, PECVD, atomic layer deposition (ALD) or sputtering), followed by a planarization process.

The frontside BEOL structure 60 is formed on top of the MOL level. The frontside BEOL structure 60 is composed of an interconnect dielectric region having frontside metal wiring embedded therein. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal (e.g., Cu, W, Al, Co or Ru) or an electrically conductive metal alloy (e.g., Al—Cu). The frontside BEOL structure 60 can be formed utilizing any well-known BEOL process including a damascene process or a subtractive metal etch process. It is noted that the frontside BEOL structure 60 is electrically connected to each of the transistors through the frontside contact structures described above.

After forming the frontside BEOL structure 60, carrier wafer 62 is formed on the frontside BEOL structure 60. Carrier wafer 62 can include a semiconductor material as defined above. Carrier wafer 62 is bonded to the frontside BEOL structure 60 utilizing any bonding process that is well known to those skilled in the art. This concludes the frontside processing of the exemplary structure, backside processing will now be performed.

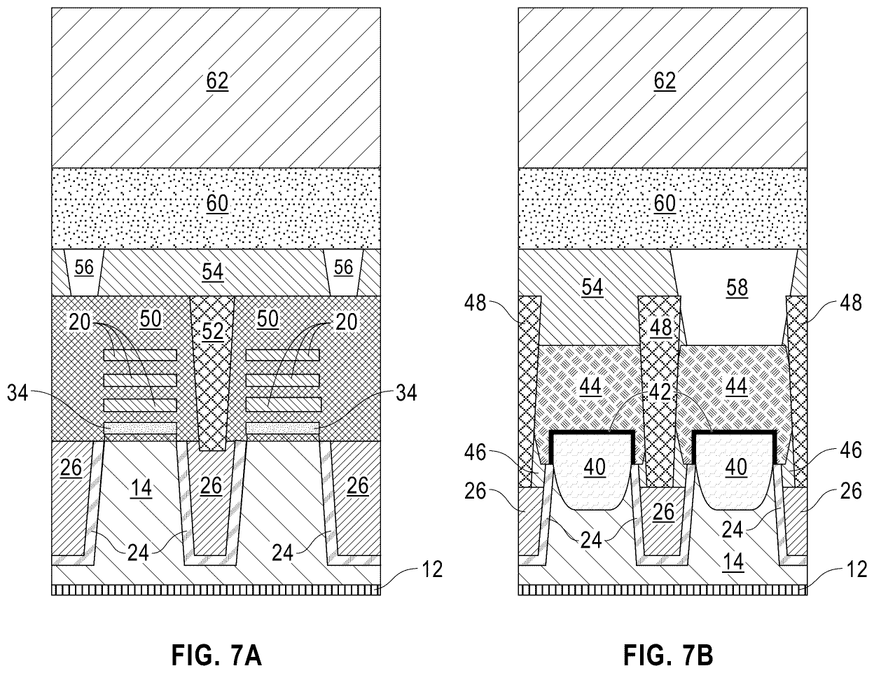

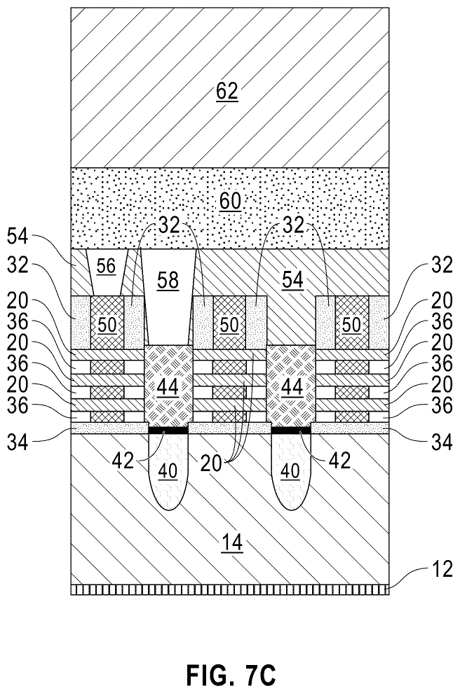

Referring now to FIGS. 7A-7C, there are illustrated the exemplary structure of FIGS. 6A-6C, respectively, after wafer flipping and removing semiconductor base layer 10 of the substrate to physically expose etch stop layer 12 of the substrate. In the present application, backside processing begins by flipping the exemplary structure 180° to physically expose a backside of the structure. For clarity, the flipping step is not shown in the drawings. Flipping can be performed by hand or by utilizing a mechanical means such as, for example, a robot arm. After flipping, and in the illustrated embodiment, the semiconductor base layer 10 is physically exposed and the physically exposed semiconductor base layer 10 is removed utilizing a material removal process that is selective in removing the semiconductor material that provides the semiconductor base layer 10. The removal of the semiconductor base layer 10 reveals the etch stop layer 12. The removal of the semiconductor base layer 10 can be omitted when no semiconductor base layer 10 is present in the substrate.

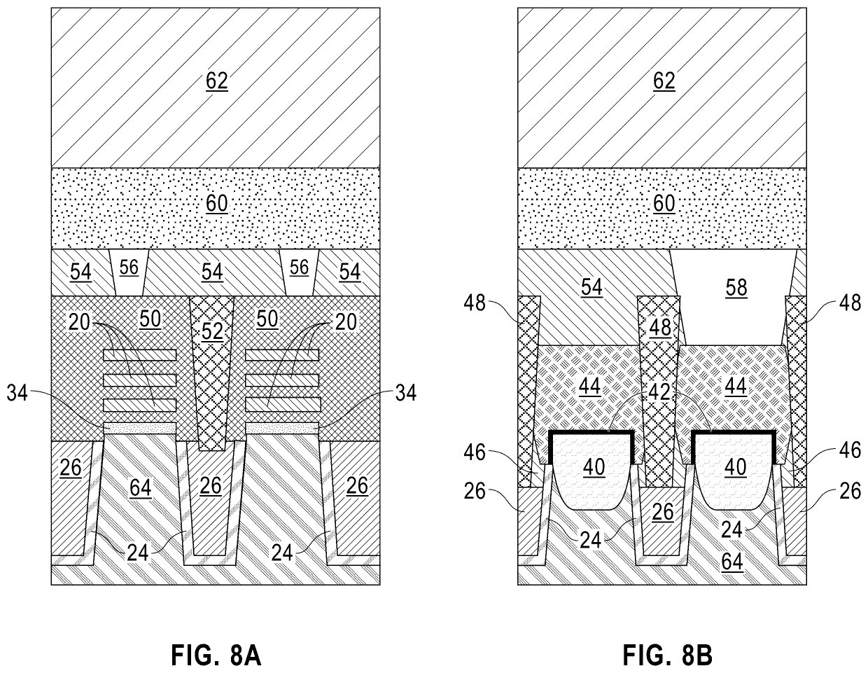

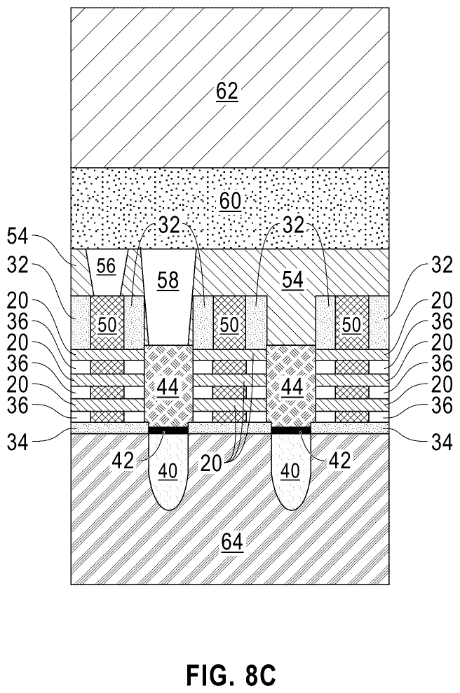

Referring now to FIGS. 8A-8C, there are illustrated the exemplary structure of FIGS. 7A-7C, respectively, after removing the etch stop layer 12 and semiconductor device layer 14 of the substrate, and forming a backside ILD layer 64. The etch stop layer 12 can be removed utilizing a material removal process that is selective in removing the material that provides the etch stop layer 12. The removal of the etch stop layer 12 physically exposes the semiconductor device layer 14. It is noted that the removal of the etch stop layer 12 can be omitted when such a layer is not present. The semiconductor device layer 14 can be removed utilizing a material removal process that is selective in removing the semiconductor device layer 14. The removal of the semiconductor device layer 14 physically exposes the bottom dielectric isolation layer 34, the shallow trench isolation structure and the backside source/drain contact placeholder structures 40.

Backside ILD layer 64 is then formed. The backside ILD layer 64 includes an ILD material including those mentioned above for the first frontside ILD layer 46. The backside ILD layer 64 can be formed by deposition, followed by planarization. The backside ILD layer 64 contacts the bottom dielectric isolation layer 34, the shallow trench isolation structure, and the backside source/drain contact placeholder structures 40. The backside ILD layer 64 embeds the backside source/drain contact placeholder structures 40.

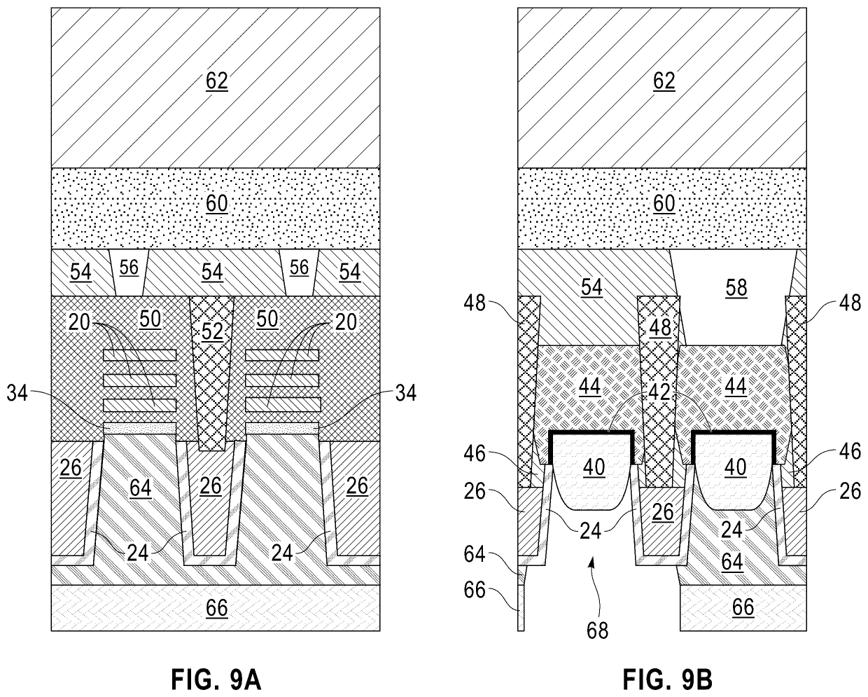

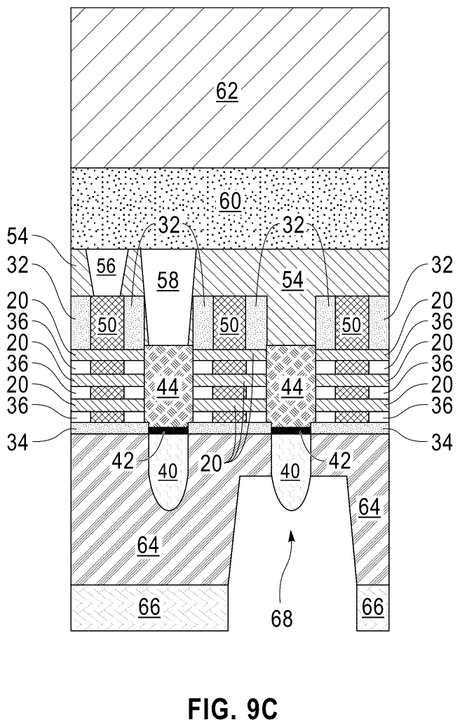

Referring now to FIGS. 9A-9C, there are illustrated the exemplary structure of FIGS. 8A-8C, respectively, after forming backside source/drain contact openings 68 that reveal some of the backside source/drain contact placeholder structures 40. The formation of the backside source/drain contact openings 68 begins by forming a patterned masking layer 66 on a horizontal surface of the backside ILD layer 64. The patterned masking layer 66 is composed of a masking material or a combination of masking materials that are well known to those skilled in the art. In one example, the masking material that provides the patterned masking layer 66 is an organic planarization material. The patterned masking layer 66 can be formed by deposition of the masking material(s), followed by lithographic patterning. After forming the patterned masking layer 66, the backside source/drain contact openings 68 formation continues by etching (e.g., RIE) through backside ILD layer 64 to physically expose some of the backside source/drain contact placeholder structures 40. After the formation of the backside source/drain contact openings 68, the patterned masking layer 66 can be removed from the structure utilizing a material removal process such as, for example, ashing, which is selective in removing the patterned masking layer 66.

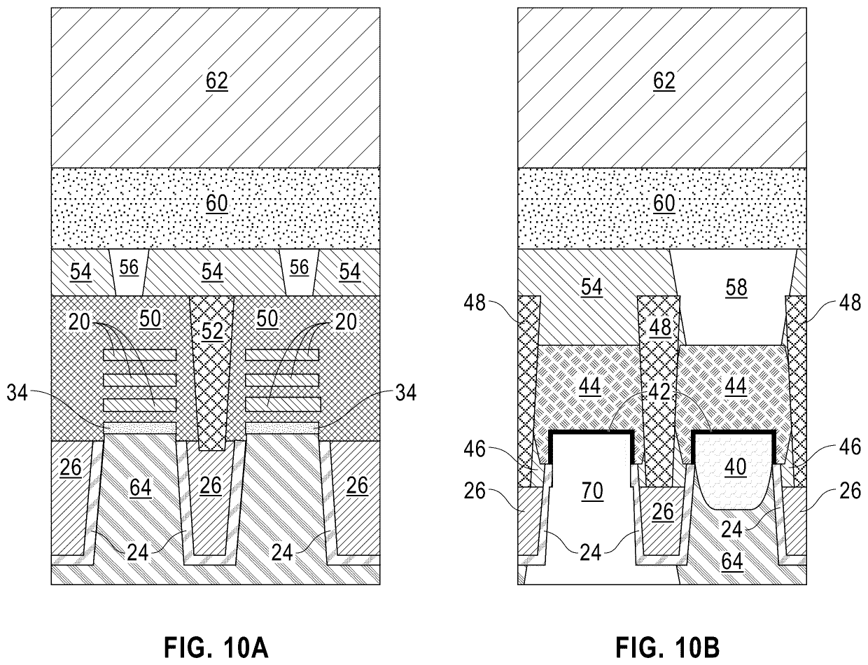

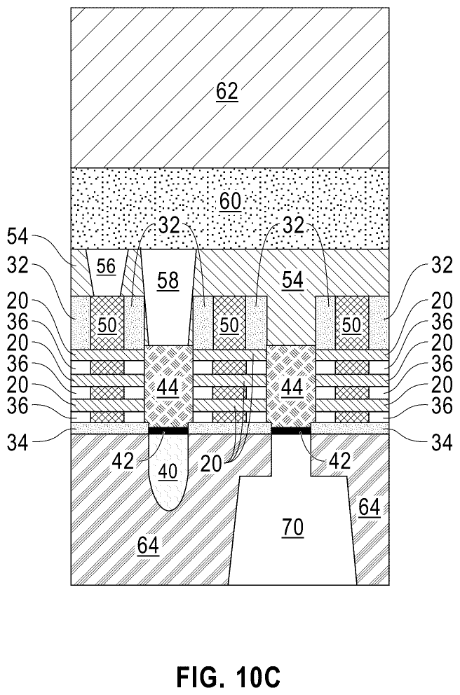

Referring now to FIGS. 10A-10C, there are illustrated the exemplary structure of FIGS. 9A-9C, respectively, after forming a backside source/drain contact structure 70 in each of the backside source/drain contact openings 68. The formation of the backside source/drain contact structure 70 begins by removing the revealed backside source/drain contact placeholder structures 40. The revealed backside source/drain contact placeholder structures 40 can be removed utilizing a material removal process such as, for example, an etch, that is selective in removing the revealed backside source/drain contact placeholder structures 40. In some embodiments, the material removal process stops on a surface of the semiconductor buffer layer 42. In other embodiments and when the semiconductor buffer layer 42 is not present, the material removal process stops on a surface of the source/drain region 44 of one of the transistors. Such an embodiment is not illustrated in the drawings, but can be readily discerned from FIGS. 10A-10C. In some embodiments in which the semiconductor buffer layer 42 is present, a punch through etching process can be performed to physically expose a surface of the source/drain region 44 of one of the transistors. The backside source/drain contact structure 70 is then formed. The backside source/drain contact structure 70 can be composed of at least a contact conductor material as mentioned above for the frontside contact structures. The backside source/drain contact structure 70 can also include one of the liners mentioned above with respect to the frontside contact structures. The backside source/drain contact structure 70 can be formed by deposition, followed by a planarization process. In the present application, the backside source/drain contact structure 70 contacts the source/drain region 44. The backside source/drain contact structure 70 has a first surface contacting a source/drain region 44 of a transistor and a second surface, opposite the first surface, that direct contacts the backside BEOL structure 72 (to be subsequently formed). Similarly, the frontside source/drain contact structures have a first surface contacting a source/drain region of a transistor and a second surface, opposite the first, that directly contacts the frontside BEOL structure 60.

It is noted that in the gate cross sectional view shown in FIG. 10C, the backside source/drain contact structure 70 is located under the bottommost surface of each gate structure 50, and no gouging feature is formed in the source/drain regions 44 (hence the volume of the source/drain regions 44 is not reduced which is the case when gouging of a source/drain region occurs). In the cross sectional view through the area including the source/drain regions 44 as is shown in FIG. 10B, an upper portion of the backside source/drain contact structure 70 is enclosed by at least one of the source/drain regions 44. Notably, one of the source/drain regions 44 (and, if present, the semiconductor buffer layer 42) wraps around the upper portion backside source/drain contact structure 70. It is further noted that in the exemplary structure a bottommost portion of the source/drain regions 44 is vertically offset from a bottommost surface of each gate structure 50. Stated in other terms, the backside source/drain contact structure 70 is located entirely beneath the gate structure 50 of the transistors.

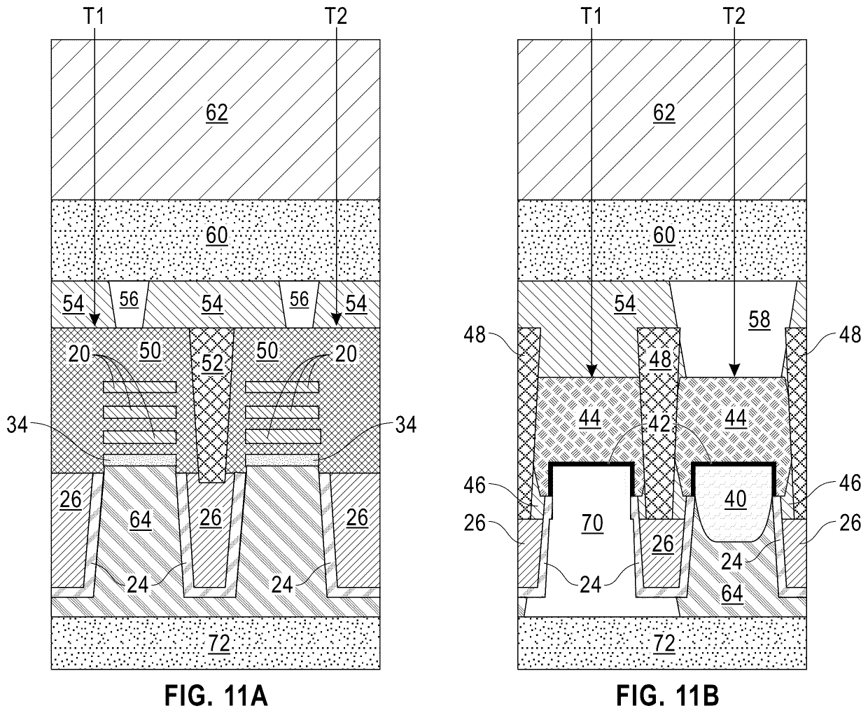

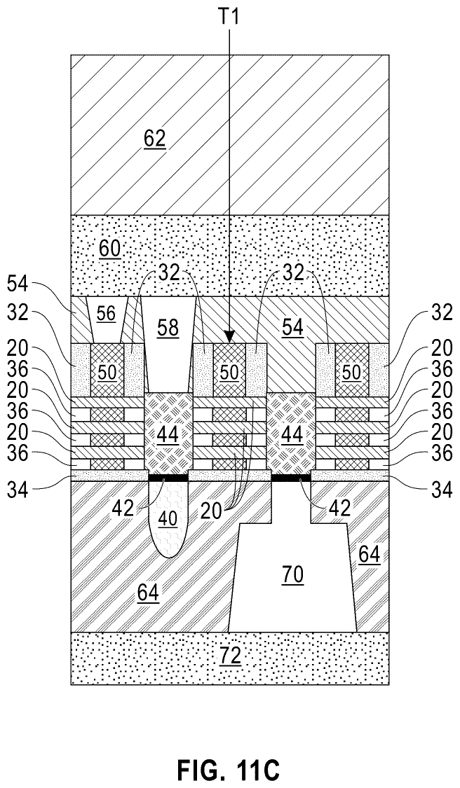

Referring now to FIGS. 11A-11C, there are illustrated the exemplary structure of FIGS. 10A-10C, respectively, after forming a backside BEOL structure 72. The backside BEOL structure 72 is formed on a surface of the backside ILD layer 64. The backside BEOL structure 72 (which can delivery power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 72 can be formed utilizing any well-known BEOL process including a damascene process or a subtractive metal etch process. It is noted that the backside BEOL structure 72 is electrically connected to each of the transistors through the backside source/drain contact structures 70.

Notably, FIGS. 11A-11C illustrate a semiconductor device in accordance with the present application. The semiconductor device includes a pair of transistors (e.g., T1 and T2) located adjacent to each other, each transistor of the pair of transistors includes gate structure 50 and source/drain regions 44. The semiconductor device further includes gate cut dielectric pillar 52 separating the gate structures 50 of the pair of transistors, dielectric pillar structure 48 separating the source/drain regions 44 of the pair of transistors, and backside BEOL structure 72 electrically connected to a first source/drain region (i.e., one of source/drain regions 44 associated with T1) of a first transistor (i.e., T1) of the pair of transistors by backside source/drain contact structure 70. In the present application, the first source/drain region wraps around an upper portion of the backside source/drain contact structure 70, and the backside source/drain contact structure 70 is located entirely beneath the gate structure 50 of the pair of transistors.

In another aspect of the present application, the semiconductor device illustrated in FIGS. 11A-11C includes a pair of transistors (e.g., T1 and T2) located adjacent to each other, each transistor of the pair of transistors includes gate structure 50 and source/drain regions 44. The semiconductor device further includes gate cut dielectric pillar 52 separating the gate structures 50 of the pair of transistors, dielectric pillar structure 48 separating the source/drain regions 44 of the pair of transistors, and backside BEOL structure 72 electrically connected to a first source/drain region (i.e., one of source/drain regions 44 associated with T1) of a first transistor T1 of the pair of transistors by backside source/drain contact structure 70. In the present application, the first source/drain region wraps around an upper portion of the backside source/drain contact structure 70, and the source/drain regions 44 have a bottommost surface that is vertically offset and located below a bottommost surface of each gate structure 50.

In any of the above embodiments, the gate cut dielectric pillar 52 lands on a surface of first shallow trench isolation (i.e., the shallow trench isolation structure shown in FIG. 11A) and the dielectric pillar structure 48 lands on a surface of a second shallow trench isolation structure (i.e., the shallow trench isolation structure shown in FIG. 11B), in which the first shallow trench isolation structure include a first trench dielectric material (i.e., trench dielectric material 26 shown in FIG. 11A) having a first height and the second shallow trench isolation structure includes a second trench dielectric material (i.e., trench dielectric material 26 shown in FIG. 11B) having a second height that is less than the first height. The first and second heights are specially shown in FIGS. 3A-3B.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a pair of transistors located adjacent to each other, each transistor of the pair of transistors comprises a gate structure and source/drain regions;
a gate cut dielectric pillar separating the gate structures of the pair of transistors;
a dielectric pillar structure separating the source/drain regions of the pair of transistors; and
a backside back-end-of-the-line (BEOL) structure electrically connected to a first source/drain region of a first transistor of the pair of transistors by a backside source/drain contact structure, wherein the first source/drain region wraps around an upper portion of the backside source/drain contact structure, and the backside source/drain contact structure is located entirely beneath the gate structure of the pair of transistors.

2. The semiconductor device of claim 1, wherein the gate cut dielectric pillar has a topmost surface that is substantially coplanar with a topmost surface of the dielectric pillar structure, and the gate cut dielectric pillar has a height that is greater than a height of the dielectric pillar structure.

3. The semiconductor device of claim 1, wherein the gate cut dielectric pillar lands on a surface of a first shallow trench isolation and the dielectric pillar structure lands on a surface of a second shallow trench isolation structure, wherein the first shallow trench isolation structure comprises a first trench dielectric material having a first height and the second shallow trench isolation structure comprises a second trench dielectric material having a second height that is less than the first height.

4. The semiconductor device of claim 1, further comprising a semiconductor buffer layer wrapping around the upper portion of the backside source/drain contact structure and positioned between the upper portion of the backside source/drain contact structure and the first source/drain region.

5. The semiconductor device of claim 1, further comprising a frontside BEOL structure electrically connected to a second source/drain region of the first transistor of the pair of transistors by a frontside source/drain contact structure.

6. The semiconductor device of claim 5, further comprising a backside source/drain contact placeholder structure located beneath the second source/drain region.

7. The semiconductor device of claim 6, further comprising a semiconductor buffer layer positioned between the backside source/drain contact placeholder structure and the second source/drain region.

8. The semiconductor device of claim 1, wherein the pair of transistors are nanosheet transistors comprising a semiconductor channel region of a vertically stacked and spaced apart semiconductor channel material nanosheets.

9. The semiconductor device of claim 8, wherein the semiconductor channel region is located above a bottom dielectric isolation layer.

10. The semiconductor device of claim 1, further comprising a frontside interlayer dielectric (ILD) layer located beneath the source/drain regions.

11. A semiconductor device comprising:
a pair of transistors located adjacent to each other, each transistor of the pair of transistors comprises a gate structure and source/drain regions;
a gate cut dielectric pillar separating the gate structures of the pair of transistors;
a dielectric pillar structure separating the source/drain regions of the pair of transistors; and
a backside back-end-of-the-line (BEOL) structure electrically connected to a first source/drain region of a first transistor of the pair of transistors by a backside source/drain contact structure, wherein the first source/drain region wraps around an upper portion of the backside source/drain contact structure, and the source/drain regions have a bottommost surface that is vertically offset and located below a bottommost surface of each gate structure.

12. The semiconductor device of claim 11, wherein the gate cut dielectric pillar has a topmost surface that is substantially coplanar with a topmost surface of the dielectric pillar structure, and the gate cut dielectric pillar has a height that is greater than a height of the dielectric pillar structure.

13. The semiconductor device of claim 11, wherein the gate cut dielectric pillar lands on a surface of a first shallow trench isolation and the dielectric pillar structure lands on a surface of a second shallow trench isolation structure, wherein the first shallow trench isolation structure comprises a first trench dielectric material having a first height and the second shallow trench isolation structure comprises a second trench dielectric material having a second height that is less than the first height.

14. The semiconductor device of claim 11, further comprising a semiconductor buffer layer wrapping around the upper portion of the backside source/drain contact structure and positioned between the upper portion of the backside source/drain contact structure and the first source/drain region.

15. The semiconductor device of claim 11, further comprising a frontside BEOL structure electrically connected to a second source/drain region of the first transistor of the pair of transistors by a frontside source/drain contact structure.

16. The semiconductor device of claim 15, further comprising a backside source/drain contact placeholder structure located beneath the second source/drain region.

17. The semiconductor device of claim 16, further comprising a semiconductor buffer layer positioned between the backside source/drain contact placeholder structure and the second source/drain region.

18. The semiconductor device of claim 11, wherein the pair of transistors are nanosheet transistors comprising a semiconductor channel region of a vertically stacked and spaced apart semiconductor channel material nanosheets.

19. The semiconductor device of claim 18, wherein the semiconductor channel region is located above a bottom dielectric isolation layer.

20. The semiconductor device of claim 19, wherein the semiconductor channel region is located above a bottom dielectric isolation layer.
